(19) United States
(12) Patent Application Publication
(10) Pub. No.: US 2024/0353759 A1
(43) Pub. Date: Oct. 24, 2024

(54) Full Wafer Measurement Based On A Trained Full Wafer Measurement Model

(71) Applicant: KLA Corporation, Milpitas, CA (US)

(72) Inventors: Stilian Ivanov Pandev, Santa Clara, CA (US); Min-Yeong Moon, Ann Arbor, MI (US)

(21) Appl. No.: 18/136,747

(22) Filed: Apr. 19, 2023

(51) Int. Cl. G03F 7/00

(52) U.S. Cl. CPC G03F 7/70625; G03F 7/706831; G03F 7/706841

(57) ABSTRACT

Methods and systems for measurements of semiconductor structures based on a trained whole wafer measurement model that is valid for all possible measurement locations on a wafer are described herein. A whole wafer measurement model is trained based on Design Of Experiments (DOE) measurement data collected across an entire wafer or set of wafers subjected to the same set of process steps. By employing DOE measurement data across an entire wafer or set of wafers, information about process behavior across the entire wafer is implicitly incorporated into the trained model at all locations across the wafer under measurement. The model training process encourages physical process behavior, which reduces the degrees of freedom of the underlying model, breaks correlations between parameters, and reduces the dimension of the solution space. As a result, measurement performance and robustness is improved.

### TECHNICAL FIELD

The described embodiments relate to metrology systems and methods, and more particularly to methods and systems for improved measurement of semiconductor structures.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical and X-ray based metrology techniques offer the potential for high throughput without the risk of sample destruction. A number of metrology based techniques including scatterometry, reflectometry, and ellipsometry implementations and associated analysis algorithms are commonly used to characterize critical dimensions, film thicknesses, composition, overlay and other parameters of nanoscale structures.

Many metrology techniques are indirect methods of measuring physical properties of a specimen under measurement. In most cases, the raw measurement signals cannot be used to directly determine the physical properties of the specimen. Instead, a measurement model is employed to estimate the values of one or more parameters of interest based on the raw measurement signals. For example, ellipsometry is an indirect method of measuring physical properties of the specimen under measurement. In general, a physics-based measurement model or a machine learning based measurement model is required to determine the physical properties of the specimen based on the raw measurement signals (e.g., αₘₑₐₛ and βₘₑₐₛ).

In some examples, a physics-based measurement model is created that attempts to predict the raw measurement signals (e.g., αₘₑₐₛ and βₘₑₐₛ) based on assumed values of one or more model parameters. As illustrated in equations (1) and (2), the measurement model includes parameters associated with the metrology tool itself, e.g., machine parameters (P_{machine}), and parameters associated with the specimen under measurement. When solving for parameters of interest, some specimen parameters are treated as fixed valued (P_{spec-fixed}) and other specimen parameters of interest are floated (P_{spec-float}), i.e., resolved based on the raw measurement signals.

$${α}_{model} = f ( {P}_{machine} , {P}_{spec - fixed} , {P}_{spec - float} ) \qquad ( 1 )$$

$${β}_{model} = g ( {P}_{machine} , {P}_{spec - fixed} , {P}_{spec - float} ) \qquad ( 2 )$$

Machine parameters are parameters used to characterize the metrology tool (e.g., ellipsometer 101). Exemplary machine parameters include angle of incidence (AOI), analyzer angle (A₀), polarizer angle (P₀), illumination wavelength, numerical aperture (NA), compensator or waveplate (if present), etc. Specimen parameters are parameters used to characterize the specimen (e.g., material and geometric parameters characterizing the structure(s) under measurement). For a thin film specimen, exemplary specimen parameters include refractive index, dielectric function tensor, nominal layer thickness of all layers, layer sequence, etc. For a CD specimen, exemplary specimen parameters include geometric parameter values associated with different layers, refractive indices associated with different layers, etc. For measurement purposes, the machine parameters and many of the specimen parameters are treated as known, fixed valued parameters. However, the values of one or more of the specimen parameters are treated as unknown, floating parameters of interest.

In some examples, the values of the floating parameters of interest are resolved by an iterative process (e.g., regression) that produces the best fit between theoretical predictions and experimental data. The values of the unknown, floating parameters of interest are varied and the model output values (e.g., α_{model} and β_{model}) are calculated and compared to the raw measurement data in an iterative manner until a set of specimen parameter values are determined that results in a sufficiently close match between the model output values and the experimentally measured values (e.g., αₘₑₐₛ and βₘₑₐₛ). In some other examples, the floating parameters are resolved by a search through a library of pre-computed solutions to find the closest match.

In some other examples, a trained machine learning based measurement model is employed to directly estimate values of parameters of interest based on raw measurement data. In these examples, a machine learning based measurement model takes raw measurement signals as model input and generates values of the parameters of interest as model output.

A machine learning based measurement model must be trained to generate useful estimates of parameters of interest for a particular measurement application. Generally, model training is based on raw measurement signals collected from a specimen having known values of the parameters of interest (i.e., Design of Experiments (DOE) data).

A machine learning based measurement model is parameterized by a number of weight parameters. Typically, the machine learning based measurement model is trained by a regression process that minimizes total output error (e.g., ordinary least squares regression). The values of the weight parameters are iteratively adjusted to minimize the differences between the known, reference values of the parameters of interest and values of the parameters of interest estimated by the machine learning based measurement model based on the measured raw measurement signals.

Typically, a physics based measurement model or a machine learning based measurement model is employed to estimate values of one or more parameters of interest independently at each measurement site. By independently performing measurements at each measurement site, measurement information from neighboring measurement sites is not utilized. Furthermore, wafer-level process information is also not utilized. This limits measurement accuracy and increases the cost of measurement.

State of the art measurement applications suffer from low measurement sensitivity to the parameters of interest and a high level of correlation among parameters of characterizing a structure under measurement. This increases measurement complexity. Often measurements are performed over long periods of time and at multiple incidence angles to break correlations and increase sensitivity. This increases measurement time and the overall cost of measurement.

In one example, overlay is measured at a single measurement site without information from neighboring sites or wafer-level process information. As a consequence, at the time of measurement at a particular measurement site, there is no information available apriori about the overlay parameter and other parameters that may be correlated to overlay. In fact, many parameters are correlated to overlay, and rather than improving the estimate of overlay, these parameters tend to reduce the robustness of the overlay measurement itself.

Future metrology applications present challenges for metrology due to increasingly small resolution requirements, multi-parameter correlation, increasingly complex geometric structures, and increasing use of opaque materials. Thus, methods and systems for improved measurement model training and parameter inference incorporating wafer level process information are desired.

### SUMMARY

Methods and systems for measurements of semiconductor structures based on a trained whole wafer measurement model are described herein. A whole wafer measurement model is trained based on Design Of Experiments (DOE) measurement data collected across an entire wafer or set of wafers subjected to the same set of process steps. Information about process behavior across the entire wafer is implicitly incorporated into the trained model at all locations across the wafer under measurement by training the model using DOE measurement data across an entire wafer or set of wafers. The model training process encourages physical process behavior, i.e., smooth map of values of one or more parameters of interest across the wafer. This reduces the degrees of freedom of the underlying model, breaks correlations between parameters, and reduces the dimension of the solution space. As a result, measurement performance and robustness is improved.

In one aspect, a whole wafer measurement model is trained based on DOE measurement data and corresponding values of one or more parameters of interest at multiple locations across one or more wafers in parallel. Data required to train a whole wafer measurement model includes a whole wafer DOE training dataset of measurement data, S^{DOE}, and corresponding trusted values of one or more parameters of interest, POI^{DOE}, at various measurement sites across one or more wafers.

In some embodiments, the whole wafer DOE training dataset includes actual measurement data collected from structures fabricated in accordance with trusted values of one or more parameters of interest across one or more wafers.

In some other embodiments, the DOE set of values of the one or more parameters of interest are known, programmed parameter values, and the corresponding whole wafer training dataset of measurement data, S^{DOE}, is generated by metrology simulation.

In some embodiments, the DOE set of values of the one or more parameters of interest are derived from a parameterized model having independent variables describing different locations on a wafer. In this manner, the parameterized model generates values of a parameter of interest at any location on a wafer for a given set of values of model parameters. The corresponding whole wafer training dataset of measurement data, S^{DOE}, is generated by metrology simulation.

In some of these embodiments, coefficient values of a parameterized model are generated randomly, and for each set of coefficient values, values of one or more parameters of interest are sampled across the wafer, i.e., based on prescribed or randomly selected locations.

In other embodiments, coefficient values of a parameterized model are generated by a fitting or training process based on measured or assumed values of the parameter of interest. Measured values include values of parameters of interest measured by a trusted metrology system. Assumed values include values of parameters of interest generated by a process simulator, e.g., ProLith®, ProEtch®, etc., or based on user experience.

In another aspect, a whole wafer measurement model is trained based on DOE measurement data and corresponding values of one or more parameters of interest at specified locations across one or more wafers. Additional information about process variation across the DOE wafers is implicitly introduced into the model by training based on both DOE measurement data and site location. In this manner, the trained whole wafer measurement model captures physical process behavior across the wafer and is further constrained to drive the model results toward a family of maps of values of the one or more parameters of interest, i.e., parameter values as functions of location on a wafer.

In another aspect, a trained whole wafer measurement model is employed to estimate values of one or more parameters of interest at measurement sites across the entire wafer under measurement. The trained whole wafer measurement model estimates a value of a parameter of interest at each specified measurement location based on the measurement data collected at that specified location. However, the trained whole wafer measurement model is valid for all possible measurement locations on a wafer.

In a further aspect, a whole wafer measurement model estimates values of coefficients characterizing a parameterized wafer map, and the estimated coefficient values are mapped to values of parameters of interest characterizing the structures under measurement at each measurement site using a trained wafer map model.

In some embodiments, a trained wafer map model is employed to synthetically generate DOE datasets as described hereinbefore. In these embodiments, whole wafer DOE sets of values of one or more parameters of interest are generated based on the parameterized model, and the corresponding whole wafer training dataset of measurement data, S^{DOE}, is determined by metrology simulation.

In another further aspect, coefficients of a parameterized wafer map are trained to accurately map a DOE set of values of one or more ancillary parameters characterizing structures under measurement across a wafer or set of wafers. The ancillary parameters are required to accurately simulate a measurement of the structures. Furthermore, the trained wafer map model is employed to synthetically generate DOE datasets of the ancillary parameters based on the parameterized model. The corresponding whole wafer training dataset of measurement data, S^{DOE}, is determined by metrology simulation based on the DOE datasets of the parameters of interest and the DOE datasets of the ancillary parameters of the structures. In this manner, the metrology simulation does not have to rely on assumed values of the ancillary parameters.

In some embodiments a whole wafer measurement model is a machine learning based measurement model. In other embodiments a whole wafer measurement model is a physics based measurement model.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 depicts an illustration of a metrology system 100 for measuring characteristics of a semiconductor structure in accordance with the exemplary methods presented herein.

FIG. 2 is a diagram illustrative of a whole wafer measurement model training engine 200 in one embodiment.

FIG. 3 is a diagram illustrative of a whole wafer measurement model training engine 215 in another embodiment.

FIG. 4 is a diagram illustrative of a trained whole wafer measurement model inference engine 220 in one embodiment.

FIG. 5 is a diagram illustrative of a trained whole wafer measurement model inference engine 230 in another embodiment.

FIG. 6 illustrates a plot 120 indicative of the tracking performance of a whole wafer measurement model trained as described with reference to FIG. 2.

FIG. 7 illustrates a plot 122 indicative of the tracking performance of a whole wafer measurement model trained as described with reference to FIG. 3.

FIG. 8 is a wafer error map 125 associated with the differences between the trusted and predicted values at each measurement site illustrated in FIG. 6.

FIG. 9 is a wafer error map 126 associated with the differences between the trusted and predicted values at each measurement site illustrated in FIG. 7.

FIG. 10 is a diagram illustrative of a trained whole wafer measurement model inference engine 240 in another embodiment.

FIG. 11 depicts a map 250 of DOE values of a parameter of interest at various measurement site locations.

FIG. 12 depicts a map 251 of values of the parameter of interest depicted in FIG. 11 as estimated by a trained 5^{th} order polynomial wafer map model in one embodiment.

FIG. 13 depicts a map 252 of values of the parameter of interest depicted in FIG. 11 as estimated by a trained 10^{th} order polynomial wafer map model in another embodiment.

FIG. 14 depicts a map 253 of values of the parameter of interest depicted in FIG. 11 as estimated by a trained neural network wafer map model in another embodiment.

FIG. 15 depicts a map 261 of values of the parameter of interest depicted in FIG. 11 as estimated by a trained 5^{th} order polynomial wafer map model in another embodiment.

FIG. 16 depicts a map 262 of values of the parameter of interest depicted in FIG. 11 as estimated by a trained 10^{th} order polynomial wafer map model in another embodiment.

FIG. 17 depicts a map 263 of values of the parameter of interest depicted in FIG. 11 as estimated by a trained neural network wafer map model in another embodiment.

FIG. 18 is a diagram illustrative of a whole wafer measurement model training engine 270 in another embodiment.

FIG. 19 is a diagram illustrative of a trained whole wafer measurement model inference engine 290 in another embodiment.

FIG. 20 illustrates a flowchart of a method 300 for training a whole wafer measurement model for estimating values of parameters of interest in one example.

### DETAILED DESCRIPTION

Reference will now be made in detail to background examples and some embodiments of the invention, examples of which are illustrated in the accompanying drawings.

Methods and systems for measurements of semiconductor structures based on a trained whole wafer measurement model are described herein. A whole wafer measurement model is trained based on Design Of Experiments (DOE) measurement data collected across an entire wafer or set of wafers subjected to the same set of process steps. Furthermore, a trained whole wafer measurement model is employed to estimate values of one or more parameters of interest at measurement sites across the entire wafer under measurement.

By employing DOE measurement data across an entire wafer or set of wafers, information about process behavior across the entire wafer is implicitly incorporated into the trained model at all locations across the wafer under measurement. As a result, the trained whole wafer measurement model estimates values of a parameter of interest across a wafer under measurement without discontinuities. The model training process encourages physical process behavior, i.e., smooth map of values of one or more parameters of interest across the wafer. This reduces the degrees of freedom of the underlying model, breaks correlations between parameters, and reduces the dimension of the solution space. As a result, measurement performance and robustness is improved.

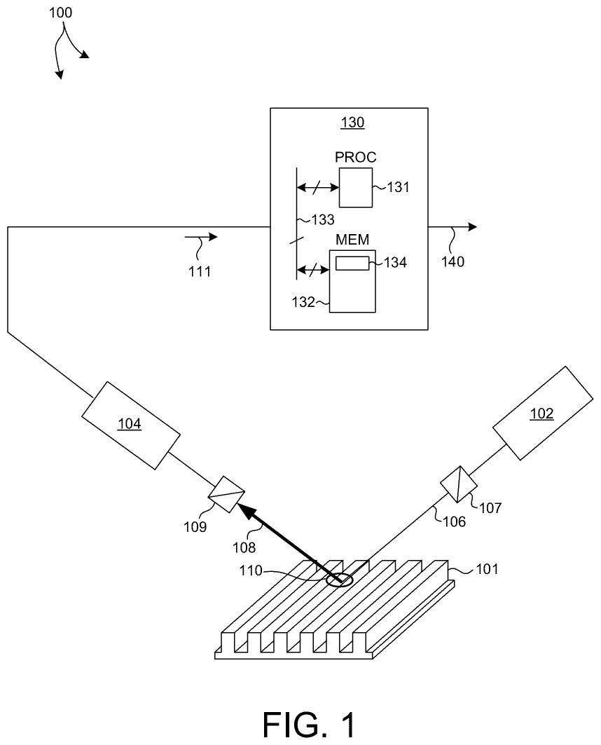

FIG. 1 illustrates a system 100 for measuring characteristics of a specimen in accordance with the exemplary methods presented herein. As shown in FIG. 1, the system 100 may be used to perform spectroscopic ellipsometry measurements of structure 101 depicted in FIG. 1. In this aspect, the system 100 may include a spectroscopic ellipsometer equipped with an illuminator 102 and a spectrometer 104. The illuminator 102 of the system 100 is configured to generate and direct illumination of a selected wavelength range (e.g., 100-2500 nm) to the structure disposed on the surface of the specimen over a measurement spot 110. In turn, the spectrometer 104 is configured to receive illumination reflected from structure 101. It is further noted that the light emerging from the illuminator 102 is polarized using a polarization state generator 107 to produce a polarized illumination beam 106. The radiation reflected by structure 101 is passed through a polarization state analyzer 109 and to the spectrometer 104. The radiation received by the spectrometer 104 in the collection beam 108 is analyzed with regard to polarization state, allowing for spectral analysis by the spectrometer of radiation passed by the analyzer. These spectra 111 are passed to the computing system 130 for analysis of the structure as described herein.

As depicted in FIG. 1, system 100 includes a single measurement technology (i.e., SE). However, in general, system 100 may include any number of different measurement technologies. By way of non-limiting example, system 100 may be configured as a spectroscopic ellipsometer (including Mueller matrix ellipsometry), a spectroscopic reflectometer, a spectroscopic scatterometer, an overlay scatterometer, an angular resolved beam profile reflectometer, a polarization resolved beam profile reflectometer, a beam profile reflectometer, a beam profile ellipsometer, any single or multiple wavelength ellipsometer, or any combination thereof. Furthermore, in general, measurement data collected by different measurement technologies and analyzed in accordance with the methods described herein may be collected from multiple tools, a single tool integrating one measurement technology, a single tool integrating multiple technologies, or a combination thereof, including, by way of non-limiting example, soft X-ray reflectometry, small angle x-ray scatterometry, an imaging based metrology system, a hyperspectral imaging based metrology system, a scatterometry overlay metrology system, etc.

In a further embodiment, system 100 may include one or more computing systems 130 employed to perform measurements of structures based on measurement models developed in accordance with the methods described herein. The one or more computing systems 130 may be communicatively coupled to the spectrometer 104. In one aspect, the one or more computing systems 130 are configured to receive measurement data 111 associated with measurements of a structure under measurement (e.g., structure 101).

In some embodiments, computing system 130 is configured to develop and train a whole wafer measurement model as well as execute the trained whole measurement model to estimate values of one or more parameters of interest as described herein.

In one aspect, a whole wafer measurement model is trained based on DOE measurement data and corresponding values of one or more parameters of interest at multiple locations across one or more wafers in parallel. In this manner, the trained whole wafer measurement model captures physical process behavior across the wafer.

A whole wafer DOE training dataset of measurement data, S^{DOE} DE, and corresponding trusted values of one or more parameters of interest, POI^{DOE}, is generated at various measurement sites across one or more wafers.

In some embodiments, the whole wafer DOE training dataset includes actual measurement data collected from structures fabricated in accordance with trusted values of one or more parameters of interest across one or more wafers. In some embodiments, the trusted values are measured by a trusted reference metrology system (e.g., SEM, TEM, etc.). In some embodiments, the trusted values of the one or more parameters of interest associated with each of the measured structures are known, programmed values employed to fabricate the measured structures. In some embodiments, the trusted values of the one or more parameters of interest associated with each of the measured structures are assumed values employed to fabricate the measured structures.

In some other embodiments, the DOE set of values of the one or more parameters of interest are known, programmed parameter values, and the corresponding whole wafer training dataset of measurement data, S^{DOE}, is generated by metrology simulation. In these examples, a metrology simulation tool simulates the training dataset of measurement data, S^{DOE}, generated by the metrology tool in response to the measurement of a structure having a known, programmed shape characterized by the DOE of parameters of interest. In some embodiments, the simulated metrology tool is the same metrology tool employed to ultimately measure structures having unknown values of one or more parameters of interest, POI^{DOE}.

In some of these embodiments, the DOE set of values of the one or more parameters of interest are derived from a parameterized model. In an example illustrated by Equation (3), the parameterized model is a second order polynomial model having two independent variables, x and y, corresponding to the Cartesian coordinate values representing different locations on a wafer. In this manner, the parameterized model generates values of a parameter of interest at any location, {x,y} on a wafer for a given set of values of the polynomial coefficients, {C₁ . . . C₆}.

$$P O I ( x , y ) = {C}_{1} {x}^{2} + {C}_{2} x y + {C}_{3} {y}^{2} + {C}_{4} x + {C}_{5} y + {C}_{6} \qquad ( 3 )$$

In some embodiments, DOE datasets are generated synthetically by determining whole wafer DOE sets of values of one or more parameters of interest based on the parameterized model, and determining the corresponding whole wafer training dataset of measurement data, S^{DOE}, by metrology simulation.

In some of these embodiments, coefficient values or a parameterized model are generated randomly, and for each set of coefficient values, e.g., {C₁ . . . C₆}, values of one or more parameters of interest are sampled across the wafer, i.e., based on prescribed or randomly selected {x,y} coordinate values.

A second order polynomial model employing a Cartesian coordinate basis is employed to characterize the DOE set of values of a parameter of interest as illustrated by Equation (3). However, in general, a polynomial model of any order and any suitable basis may be contemplated within the scope of this patent document. In some examples, a principle component analysis of measured or assumed values of a parameter of interest across a wafer may be analyzed, e.g., by a principal component analysis, to arrive at a suitable basis of a parameterized model.

In the example illustrated by Equation (3), the parameterized model includes two independent variables, x and y, corresponding to the Cartesian coordinate values representing different locations on a wafer. However, in some other examples, the parameterized model includes four independent variables: two independent variables, x and y, corresponding to the Cartesian coordinate values representing different locations on the wafer and two additional independent variables, fieldₓ and field_{y}, corresponding to the Cartesian coordinate values representing different locations within a field on the wafer, i.e., POI (x, y, fieldₓ, field_{y}).

In some other embodiments, a parameterized model characterizing a DOE set of values of a parameter of interest may be a machine learning based model, e.g., a neural network based model. In these examples, the coefficients of the neural network model may be trained based on measured or assumed values of a parameter of interest across a wafer.

Coefficients of a parameterized model of values of a parameter of interest across a wafer may be selected randomly or by a fitting or training process based on measured or assumed values of the parameter of interest. Measured values include values of parameters of interest measured by a trusted metrology system. Assumed values include values of parameters of interest generated by a process simulator, e.g., ProLith®, ProEtch®, etc., or based on user experience.

Corresponding whole wafer DOE measurement data, S^{DOE}, is generated by metrology simulation based on the determined values of the one or more parameters of interest at each sampled wafer location and each set of coefficient values. These synthetically generated DOE datasets are subsequently employed to train a whole wafer measurement model. Real measurements are more accurately represented by synthetically generated whole wafer DOE measurement data, in comparison to random sampling, because real wafer profiles and process variation are represented in the simulation. As a result, the use of synthetically generated DOE datasets generally leads to improved robustness.

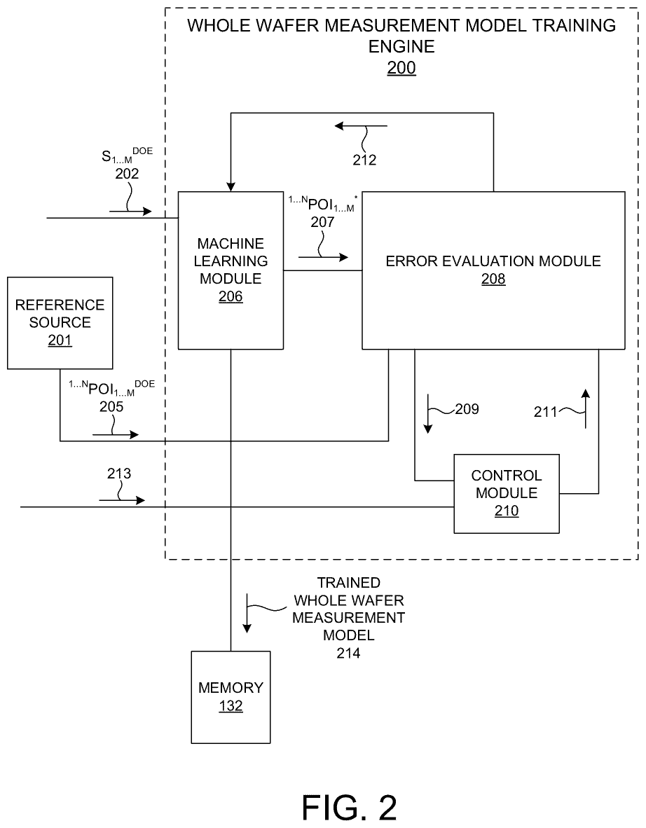

FIG. 2 is a diagram illustrative of a whole wafer measurement model training engine 200 in one embodiment. In some embodiments, computing system 130 is configured as a whole wafer measurement model training engine 200 as described herein. As depicted in FIG. 2, whole wafer measurement model training engine 200 includes a machine learning module 206, an error evaluation module 208, and a control module 210. A training dataset of whole wafer measurement data, S_{1 . . . M}^{DOE} 202, is provided as input to machine learning module 206, along with corresponding, trusted values of the parameters of interest, ^{1 . . . N}POI_{1 . . . M}^{DOE} 205.

The training dataset of whole wafer measurement data, S_{1 . . . M}^{DOE} 202, includes measurement data associated with measurements at M different measurement sites across a wafer or set of wafers, where M is any non-negative integer value. The corresponding, trusted values of the parameters of interest, ^{1 . . . N}POI_{1 . . . M}^{DOE} 205, includes the values of each of N parameters of interest at each of the M different measurement sites, where N is any non-negative integer value.

In some examples, the whole wafer measurement model is a neural network model. As depicted in FIG. 2, machine learning module 206 evaluates a neural network model for data sets S_{1 . . . M}^{DOE} 202. The output of the neural network model is an estimated value of each of the parameters of interest at each measurement location, ^{1 . . . N}POI_{1 . . . M}* 207, communicated to error evaluation module 208. Error evaluation module 208 compares the estimated values of the parameters of interest, ^{1 . . . N}POI_{1 . . . M}* 207, determined by the neural network model with the corresponding trusted values of the parameters of interest, ^{1 . . . N}POI_{1 . . . M}^{DOE} 205. Error evaluation module 208 updates the neural network weighting values 212 to minimize a function characterizing a difference between determined and trusted values of the parameters of interest (e.g., quadratic error function, linear error function, or any other suitable difference function). The updated neural network weighting values 212 are communicated to machine learning module 206. Machine learning module 206 updates the neural network model with the updated neural network weighting values for the next iteration of the training process. The iteration continues until the function characterizing a difference between determined and known values of the parameters of interest is minimized. The resulting trained whole wafer measurement model 214 is communicated to memory (e.g., memory 132).

As depicted in FIG. 2, whole wafer measurement model training engine 200 receives values of the parameters of interest, ^{1 . . . N}POI_{1 . . . M}^{DOE} 205, from a reference source 201. Reference source 201 is a trusted metrology system, a simulator, or both, employed to generate a DOE set of measurement data and corresponding DOE parameter values as described hereinbefore.

In a further aspect, a whole wafer measurement model is trained by dynamically controlling the weights associated with one or more measurement performance metrics employed to regularize the optimization driving the measurement model training process. By way of non-limiting example, critical performance metrics include R-squared (R²), Slope, Gage Repeatability and Reproducibility (GRR), etc. At each training iteration, measurement model training engine 200 checks model performance with respect to each performance metric. This information is provided as input to a dynamic controller that adjusts the weights of each different performance objective at each iteration.

Measurement model training engine 200 trains a measurement model based on an optimization function regularized by the one or more measurement performance metrics, while dynamically controlling the weights associated with each regularization term of the optimization function. In some examples, the measurement model is a neural network model. As depicted in FIG. 2, machine learning module 206 evaluates a neural network model, h(⋅) for data set S_{1 . . . M}^{DOE} 202.

At each iteration of the training process, control module 210 determines an updated value of each regularization weighting term, γₖ, associated with each measurement objective. Each updated value is determined based on the achieved value of the measurement objective and a desired value of each measurement objective. As depicted in FIG. 2, control module 210 receives an indication 209 of the value of each achieved measurement objective and the desired value of each measurement objective 213. At each iteration, control module 210 compares the achieved and desired values associated with each measurement objective and determines an updated value of each regularization weighting term 211. The updated value of each regularization weighting term 211 is communicated to loss evaluation module 208. Loss evaluation module 208 evaluates the optimization function using the updated values 211 at the next iteration.

By continuously adjusting the weights of each measurement objective during the training process, the neural network is trained to achieve the desired specifications of each of the measurement objectives with less computational effort.

Control module 210 employs a controller that optimizes for multiple measurement objectives. By way of non-limiting example, the controller is any of a Linear Quadratic Regulator (LQR) based controller, a proportional-integral-derivative (PID) controller, an optimal controller, an adaptive controller, a model predictive controller, etc.

In some embodiments, parameters of the controller are optimized for robust performance by a search algorithm, such as a genetic algorithm, a simulated annealing algorithm, a gradient descent algorithm, etc.

In some examples, each measurement performance metric is represented as a separate distribution. In one example, the distribution of measurement precision is an inverse gamma distribution. Equation (1) illustrates a probability density function, p, for measurement precision dataset, x, where, Γ(⋅) denotes the gamma function, the constant, a, denotes a shape parameter, and the constant, b, denotes a scale parameter.

$$p ( x ; a , b ) = \frac{{b}^{{a}_{x} - a - 1}}{Γ ( a )} exp ( - \frac{b}{x} ) \qquad ( 1 )$$

In another example, the distribution of mean values of instances of a measured structure over a wafer is described by a normal distribution. Equation (2) illustrates a probability density function, m, for measurement wafer mean dataset, x, where, μ, denotes a specific mean and, σ, denotes a specific variance associated with the distribution.

$$m ( x ; μ , {σ}^{2} ) = \frac{1}{\sqrt{2 {πσ}^{2}}} exp - \frac{{( x - μ )}^{2}}{2 {σ}^{2}} \qquad ( 2 )$$

In a further aspect, the statistical information characterizing actual measurement data collected from structures, e.g., the known distributions associated with important measurement performance metrics such as measurement precision, wafer mean, etc., are specifically employed to regularize the optimization that drives measurement model training.

At each iteration, the optimization function drives changes to the weighting values, W, and bias values, b, of the neural network model that minimize the optimization function. When the optimization function reaches a sufficiently low value, the measurement model is considered trained, and the trained measurement model 214 is stored in memory (e.g., memory 132).

In some examples, multiple metrics characterizing measurement tracking performance stably and quickly converge to final values. In one example, the multiple metrics include the R² value, slope value, and precision value associated with the measurement of a critical dimension of a DOE structure. In addition, the weighting values associated with the term of the objective function associated with each of the multiple metrics quickly and stably converges to a small number as the desired value of the performance objective is achieved.

In another aspect, a whole wafer measurement model is trained based on DOE measurement data and corresponding values of one or more parameters of interest at specified locations across one or more wafers. In this manner, the trained whole wafer measurement model captures physical process behavior across the wafer and is further constrained to drive the model results toward a family of maps of values of the one or more parameters of interest, i.e., parameter values as functions of location on a wafer.

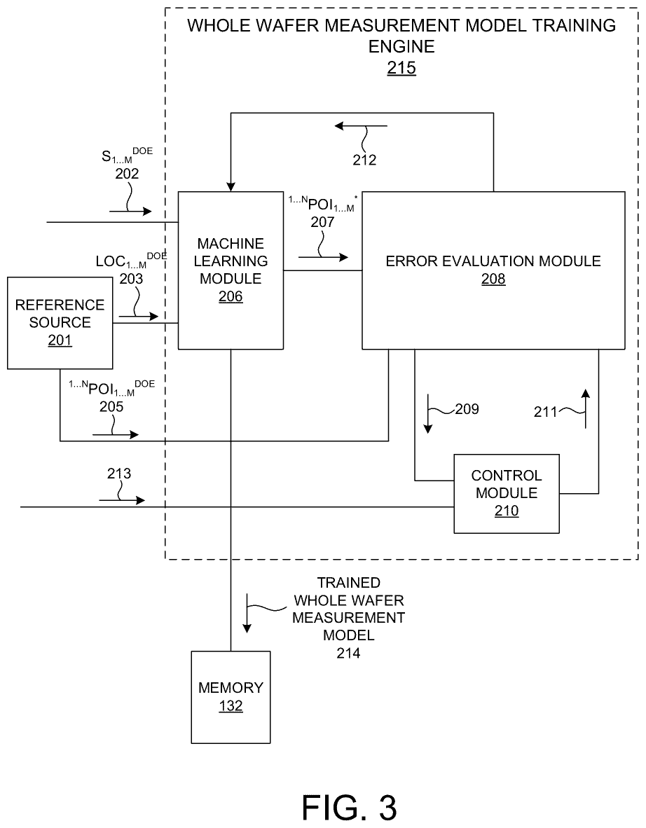

FIG. 3 is a diagram illustrative of a whole wafer measurement model training engine 215 in one embodiment. Reference numerals illustrated in FIG. 3 are analogous to the same reference numerals illustrated in FIG. 2. As depicted in FIG. 3, both a training dataset of whole wafer measurement data, S_{1 . . . M}^{DOE} 202, and each corresponding wafer location, LOC_{1 . . . M}^{DOE} 203, are provided as input to machine learning module 206.

As depicted in FIG. 3, machine learning module 206 evaluates a neural network model for measurement data, S_{1 . . . M}^{DOE} 202, associated with each location of the set of M measurement sites. The output of the neural network model is an estimated value of each of the parameters of interest at each measurement location, ^{1 . . . N}POI_{1 . . . M}* 207, communicated to error evaluation module 208. Error evaluation module 208 compares the estimated values of the parameters of interest, ^{1 . . . N}POI_{1 . . . M}* 207, determined by the neural network model at each specified location, LOC_{1 . . . M}^{DOE} 203, with the corresponding trusted values of the parameters of interest, ^{1 . . . N}POI_{1 . . . M}^{DOE} 205. Error evaluation module 208 updates the neural network weighting values 212 to minimize a function characterizing a difference between determined and trusted values of the parameters of interest (e.g., quadratic error function, linear error function, or any other suitable difference function). The updated neural network weighting values 212 are communicated to machine learning module 206. Machine learning module 206 updates the neural network model with the updated neural network weighting values for the next iteration of the training process. The iteration continues until the function characterizing a difference between determined and known values of the parameters of interest is minimized. The resulting trained whole wafer measurement model 214 is communicated to memory (e.g., memory 132).

Using both DOE measurement data, e.g., spectra, and the site location associated with each measurement as input for training of the whole wafer measurement model implicitly introduces additional information about process variation across the DOE wafers. This improves the robustness of the trained whole wafer measurement model.

In general, a location conditioned whole wafer measurement is trained based on location information and corresponding DOE measurement datasets generated to resemble process induced variations across a wafer. In some examples, multiple, random and smooth wafer maps are simulated to provide the location and DOE measurement data as described hereinbefore. DOE measurement samples are collected across a large number of different measurement sites, across different wafers and wafer lots to learn the process behavior critical to enable accurate whole wafer measurements.

In another further aspect, a trained whole wafer measurement model is employed to predict the values of parameters of interest across a wafer based on actual measured signals (e.g., spectra) collected across the wafer by a measurement system (e.g., metrology system 100). In some embodiments, the measurement system is the same measurement system employed to collect DOE measurement data. In other embodiments, the measurement system is the system simulated to generate DOE measurement data synthetically. In one example, the actual measurement data includes measured spectra 111 collected by metrology system 100 from one or more metrology targets having unknown values of the one or more parameters of interest.

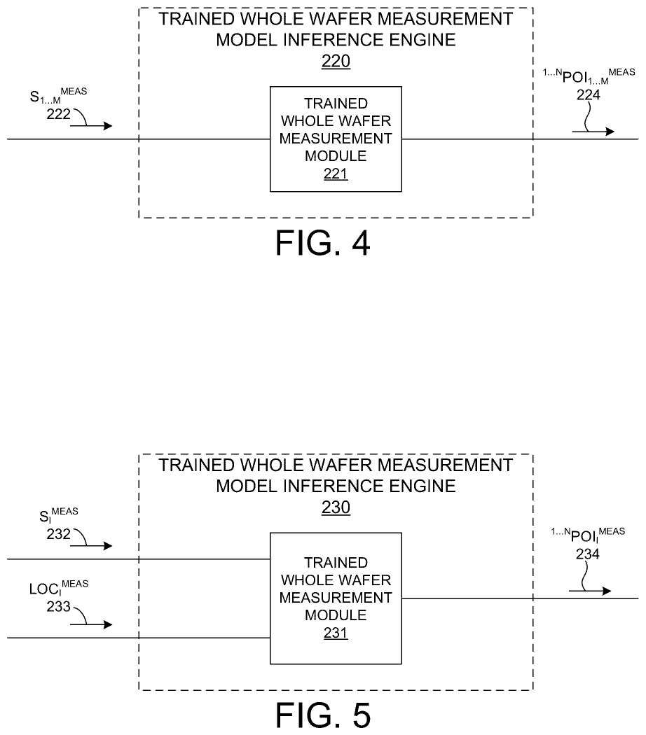

FIG. 4 is a diagram illustrative of a trained whole wafer measurement model inference engine 220 in one embodiment. As depicted in FIG. 4, trained whole wafer measurement model inference engine 220 includes a trained whole wafer measurement module 221. In the embodiment depicted in FIG. 4, measured data, S_{1 . . . M}^{MEAS} 222, collected by a metrology system or combination of metrology systems at M measurement sites is provided as input to the trained whole wafer measurement module 221. The trained whole wafer measurement module 221 employs the trained whole wafer measurement model to determine values of N parameters of interest, ^{1 . . . N}POI_{1 . . . M}^{MEAS} 224 corresponding to the M measurement sites measured across the wafer. In these embodiments, the measurement of the values of the parameters of interest is performed at all measurement sites across the wafer in parallel, i.e., all sites together.

FIG. 5 is a diagram illustrative of a trained whole wafer measurement model inference engine 230 in another embodiment. As depicted in FIG. 5, trained whole wafer measurement model inference engine 230 includes a trained whole wafer measurement module 231 trained in the manner described with reference to FIG. 3. In the embodiment depicted in FIG. 5, measured data, Sᵢ^{MEAS} 232, collected by a metrology system or combination of metrology systems at a particular measurement site and a set of coordinates describing the location of the measurement site on the wafer, LOCᵢ^{MEAS} 233, are provided as input to the whole wafer measurement module 231. The trained whole wafer measurement module 231 employs the trained whole wafer measurement model to determine values of one or more parameters of interest, ^{1 . . . N}POIᵢ^{MEAS} 224, at the location corresponding to the input value of the measurement, location, LOCᵢ^{MEAS} 233. In these embodiments, the measurement of the value of the parameter of interest is performed at each measurement site across the wafer in sequence, i.e., each measurement is conditioned on the location of the measurement site on the wafer.

The trained whole wafer measurement model estimates a value of a parameter of interest at each specified measurement location based on the measurement data collected at that location. However, the trained whole wafer measurement model is valid for all possible measurement locations on a wafer.

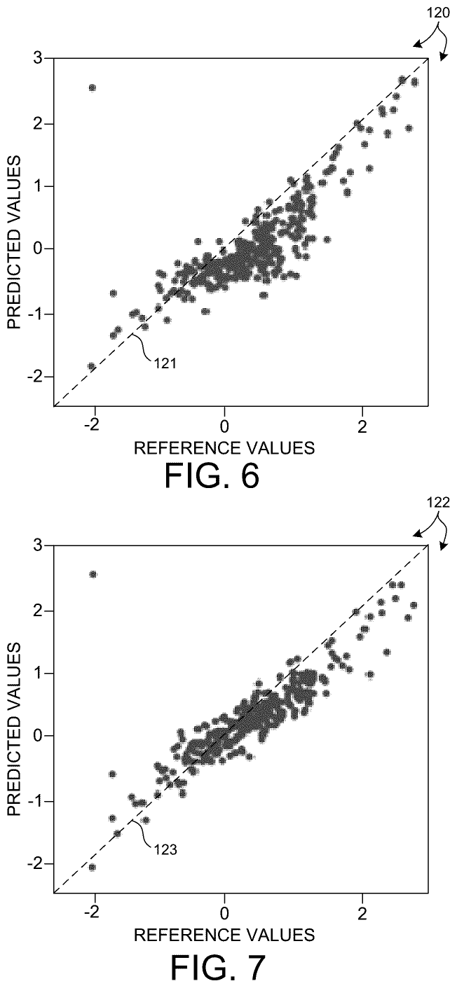

FIG. 6 illustrates a plot 120 indicative of tracking performance. As illustrated in FIG. 6, the x-location of each data point on plot 120 indicates the trusted reference value of a parameter of interest (e.g., DOE reference value) at a particular measurement site and the y-location of each data point indicates the predicted value of the parameter of interest at the same measurement site using a trained whole wafer measurement model trained as described with reference to FIG. 2. Ideal tracking performance is indicated by dashed line 121. If all predicted values perfectly matched the corresponding known, trusted values, all data points would lie on line 121. However, in practice, tracking performance is not perfect. As depicted in FIG. 6, the correlation between the known and predicted values is characterized by an R² value of 0.79.

FIG. 7 illustrates a plot 122 indicative of tracking performance. As illustrated in FIG. 7, the x-location of each data point on plot 122 indicates the trusted reference value of a parameter of interest (e.g., DOE reference value) at each measurement site and the y-location of each data point indicates the predicted value of the parameter of interest at the same measurement site using a trained whole wafer measurement model trained as described with reference to FIG. 3. Ideal tracking performance is indicated by dashed line 123. If all predicted values perfectly matched the corresponding known, trusted values, all data points would lie on line 123. However, in practice, tracking performance is not perfect. As depicted in FIG. 7, the correlation between the known and predicted values is characterized by an R² value of 0.88.

As illustrated by FIGS. 6 and 7, a whole wafer measurement model trained with measurement location input improves correlation between trusted and predicted values of a parameter of interest.

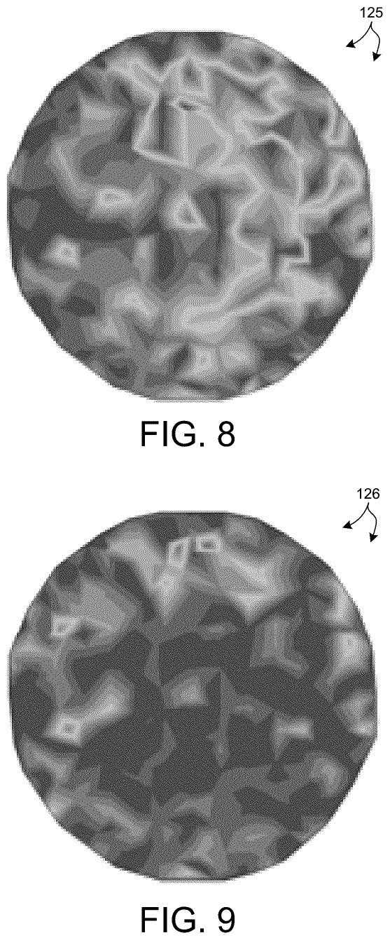

FIG. 8 is a wafer error map 125 associated with the differences between the trusted and predicted values at each measurement site illustrated in FIG. 6.

FIG. 9 is a wafer error map 126 associated with the differences between the trusted and predicted values at each measurement site illustrated in FIG. 7. As illustrated in FIGS. 8 and 9, a whole wafer measurement model trained with measurement location input reduces errors across the wafer and smooths out the error map, i.e., reduces the error gradient across the wafer.

In another aspect, a whole wafer measurement model estimates values of coefficients characterizing a parameterized wafer map, and the estimated coefficient values are mapped to values of parameters of interest characterizing the structures under measurement at each measurement site.

In one aspect, coefficients of a parameterized wafer map are trained to accurately map a DOE set of values of one or more parameters of interest characterizing structures under measurement across a wafer or set of wafers.

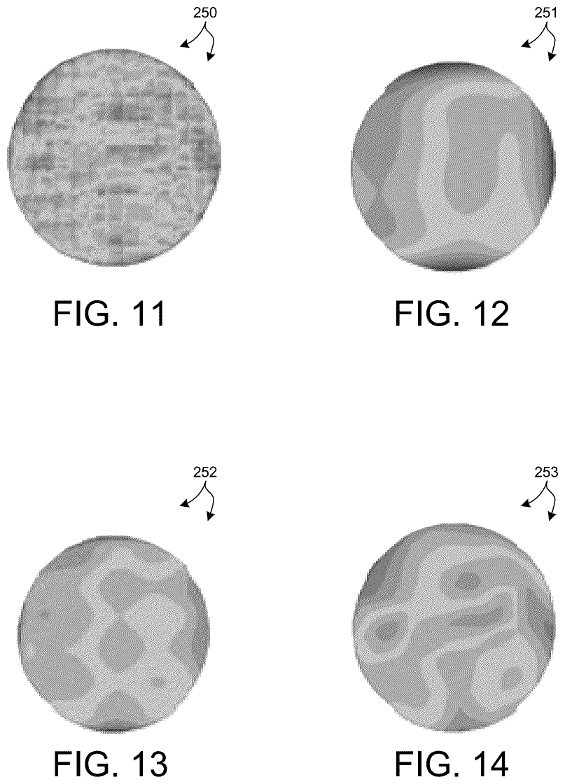

FIG. 11 depicts a map 250 of DOE values of a parameter of interest, e.g., overlay, at various measurement site locations within each field of a wafer.

FIG. 12 depicts a map 251 of values of the parameter of interest depicted in FIG. 11 as estimated by a trained 5^{th} order polynomial wafer map model at various measurement site locations across the entire wafer.

FIG. 13 depicts a map 252 of values of the parameter of interest depicted in FIG. 11 as estimated by a trained 10^{th} order polynomial wafer map model at various measurement site locations across the entire wafer.

FIG. 14 depicts a map 253 of values of the parameter of interest depicted in FIG. 11 as estimated by a trained neural network wafer map model at various measurement site locations across the entire wafer.

In the examples illustrated in FIGS. 12-14, the wafer map models are parameterized by two independent variables, x and y, corresponding to the Cartesian coordinate values representing different wafer locations.

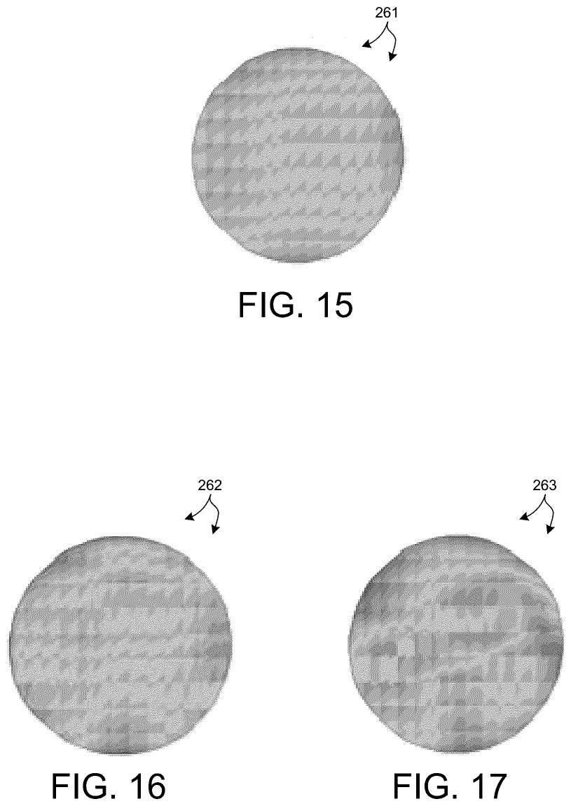

FIG. 15 depicts a map 261 of values of the parameter of interest depicted in FIG. 11 as estimated by a trained 5^{th} order polynomial wafer map model at various measurement site locations within each field of the wafer.

FIG. 16 depicts a map 262 of values of the parameter of interest depicted in FIG. 11 as estimated by a trained 10^{th} order polynomial wafer map model at various measurement site locations within each field of the wafer.

FIG. 17 depicts a map 263 of values of the parameter of interest depicted in FIG. 11 as estimated by a trained neural network wafer map model at various measurement site locations within each field of the wafer.

In the examples illustrated in FIGS. 15-17, the wafer map models are parameterized by four independent variables: two independent variables, x and y, corresponding to the Cartesian coordinate values representing different wafer locations and two additional independent variables, fieldₓ and field_{y}, corresponding to the Cartesian coordinate values representing different locations within any field on the wafer. The same number of measurement sites and measurement site locations are employed to arrive at the results illustrated in FIGS. 12-17. The differences are the result of the three different modeling approaches (5^{th} order polynomial, 10^{th} order polynomial, and trained neural network) and the number of different independent variables.

As depicted in FIGS. 12-14 and FIGS. 15-17, a trained neural network model more accurately predicts the DOE values of the parameter of interest depicted in FIG. 11 compared to the 10^{th} order polynomial model, which in turn, more accurately predicts the DOE values of the parameter of interest depicted in FIG. 11 compared to the 5^{th} order polynomial model. Furthermore, the models parameterized by both the x and y wafer locations and the x and y field locations more accurately predict the DOE values of the parameter of interest depicted in FIG. 11 compared to the models parameterized by the x and y wafer locations.

As depicted in FIGS. 12-14 and FIGS. 15-17, high frequency local variations are more accurately captured using higher order models, e.g., higher order polynomial models or neural network models with a larger number of nodes. In addition, high frequency local variations are more accurately captured when the models are parameterized by both the x and y wafer locations and the x and y field locations.

After the coefficients of a parameterized wafer map are trained to accurately map a DOE set of values of one or more parameters of interest, a whole wafer measurement model is trained based on DOE measurement data corresponding to the determined coefficients of the parameterized wafer map at multiple locations across one or more wafers in parallel. The training process is analogous to that described with reference to FIG. 2, except the DOE values of the parameters of interest, ^{1 . . . N}POI_{1 . . . M}^{DOE} 205 are replaced by the DOE values of the coefficients of the trained wafer map model, WMP_{1 . . . U}^{DOE}, and the estimated values of the parameters of interest, ^{1 . . . N}POI_{1 . . . M}* 207 are replaced by the estimated values of the coefficients of the trained wafer map model, WMP_{1 . . . U}* 207. In this manner, the trained whole wafer measurement model captures physical process behavior across the wafer.

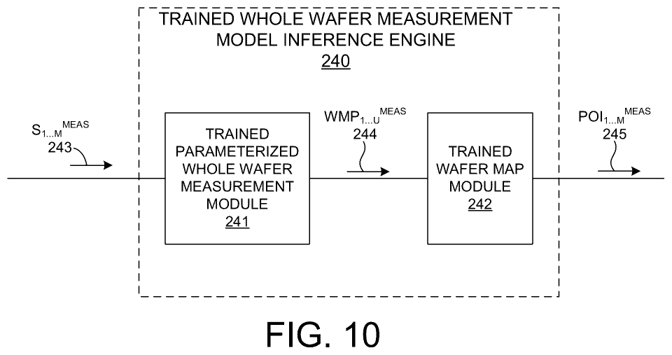

FIG. 10 is a diagram illustrative of a trained whole wafer measurement model inference engine 240 in another embodiment. As depicted in FIG. 10, trained whole wafer measurement model inference engine 240 includes a trained whole wafer measurement module 241 and a trained wafer map module 242. In the embodiment depicted in FIG. 10, measured data, S_{1 . . . M}^{MEAS} 243, collected by a metrology system or combination of metrology systems at M measurement sites is provided as input to the trained whole wafer measurement module 241. The trained whole wafer measurement module 241 employs the trained whole wafer measurement model to determine values of U coefficients, WMP_{1 . . . U}^{MEAS} 244, defined by the trained wafer map. The determined coefficient values are communicated to trained wafer map module 242. The trained wafer map module 242 maps the determined coefficient value to values of a parameter of interest at each measurement location, POI_{1 . . . M}^{MEAS} 245 corresponding to the M measurement sites measured across the wafer based on the trained wafer map. In these embodiments, the measurement of the values of the parameters of interest is performed at all measurement sites across the wafer in parallel, i.e., all sites together.

In general, any parameterized mathematical function may be employed as a parameterized wafer map, e.g., principle component model, neural network model, polynomial model, discrete cosine transform model, wavelet model, etc. The coefficients of the parameterized mathematical function are selected to best fit the DOE map of values of each parameter of interest characterizing the structures under measurement.

In a further aspect, a trained wafer map model is employed to synthetically generate DOE datasets as described hereinbefore. In these embodiments, whole wafer DOE sets of values of one or more parameters of interest are generated based on the parameterized model, and the corresponding whole wafer training dataset of measurement data, S^{DOE}, is determined by metrology simulation.

In another further aspect, coefficients of a parameterized wafer map are trained to accurately map a DOE set of values of one or more ancillary parameters characterizing structures under measurement across a wafer or set of wafers. The ancillary parameters are required to accurately simulate a measurement of the structures. Normally, the values of these parameters, e.g., underlayer parameters, are assumed and variations of these parameters across a wafer are not modelled for purposes of metrology simulation.

Furthermore, the trained wafer map model is employed to synthetically generate DOE datasets of the ancillary parameters based on the parameterized model. The corresponding whole wafer training dataset of measurement data, S^{DOE}, is determined by metrology simulation based on the DOE datasets of the parameters of interest and the DOE datasets of the ancillary parameters of the structures. In this manner, the metrology simulation does not have to rely on assumed values of the ancillary parameters.

In some embodiments, DOE datasets are generated by a process simulator that generates wafer maps based on specific process settings. A trained wafer map is subsequently employed to generate synthetic spectra and reference values of parameters of interest to train metrology models as described hereinbefore.

In some embodiments a whole wafer measurement model is a physics based measurement model. Measurements of parameters of interest are measured in parallel across multiple measurement sites on a wafer by regression on measurement data, e.g., spectral fitting, on all measurement sites together using a trained, physics based measurement model.

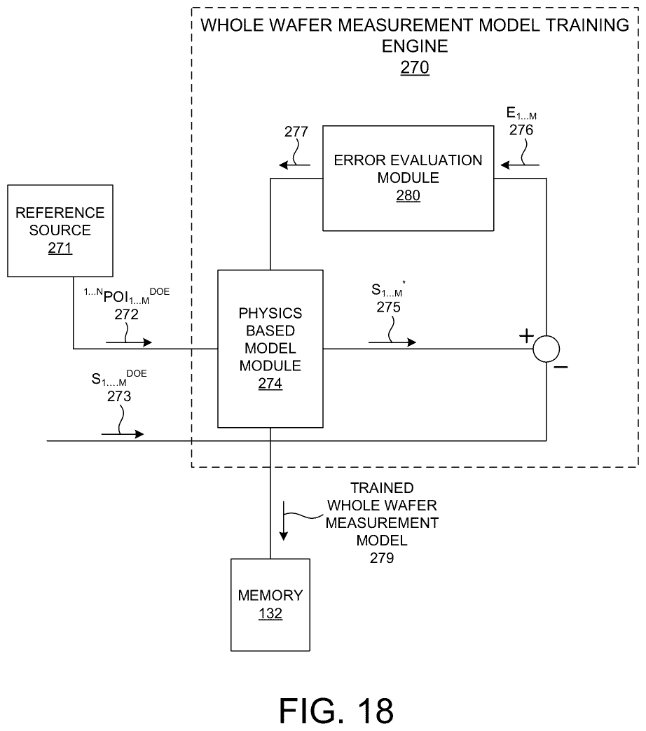

FIG. 18 is a diagram illustrative of a whole wafer measurement model training engine 270 in another embodiment. In some embodiments, computing system 130 is configured as a whole wafer measurement model training engine 270 as described herein. As depicted in FIG. 18, whole wafer measurement model training engine 270 includes a physics based model module 274 and an error evaluation module 280. A training dataset of whole wafer measurement data, S_{1 . . . M}^{DOE} 273, is provided as input to physics based model module 274, along with corresponding, trusted values of the parameters of interest, ^{1 . . . N}POI_{1 . . . M}^{DOE} 272.

As depicted in FIG. 18, whole wafer measurement model training engine 270 receives values of the DOE parameters of interest, ^{1 . . . N}POI_{1 . . . M}^{DOE} 272, from a reference source 271. Reference source 271 is a trusted metrology system, a simulator, or both, employed to generate DOE parameter values as described hereinbefore.

The training dataset of whole wafer measurement data, S_{1 . . . M}^{DOE} 273, includes measurement data associated with measurements at M different measurement sites across a wafer or set of wafers, where M is any non-negative integer value. The corresponding, trusted values of the parameters of interest, ^{1 . . . N}POI_{1 . . . M}^{DOE} 273, includes measurement data associated with parameters of interest at each of the M different measurement sites, where N is any non-negative integer value.

As depicted in FIG. 18, physics based model module 274 evaluates a physics based model based on the trusted values of the parameters of interest, ^{1 . . . N}POI_{1 . . . M}^{DOE} 272. The output of the physics based model is estimated whole wafer measurement data, S_{1 . . . M}* 275, at the M measurement sites associated with the trusted values of the parameters of interest. The estimated whole wafer measurement data, S_{1 . . . M}* 275, is compared to the DOE whole wafer measurement data, S_{1 . . . M}^{DOE} 273. Error evaluation module 280 updates the values of floated variables 277 of the physics based model to minimize a function characterizing a difference between the estimated whole wafer measurement data, S_{1 . . . M}* 275, and the DOE whole wafer measurement data, S_{1 . . . M}^{DOE} 273. During the training phase, the floated parameters are typically model parameters such as material parameters and geometric parameters that are not the parameters of interest, but parameters that require tuning to ensure the accuracy of the physics based model.

The updated values of floated variables 277 are communicated to the physics based model module 274. Physics based model module 274 updates the physics based model with the updated values of the floated variables 277 for the next iteration of the training process. The iteration continues until the function characterizing a difference between determined and DOE values of the whole wafer measurement data is minimized. The resulting trained whole wafer measurement model 279 is communicated to memory (e.g., memory 132).

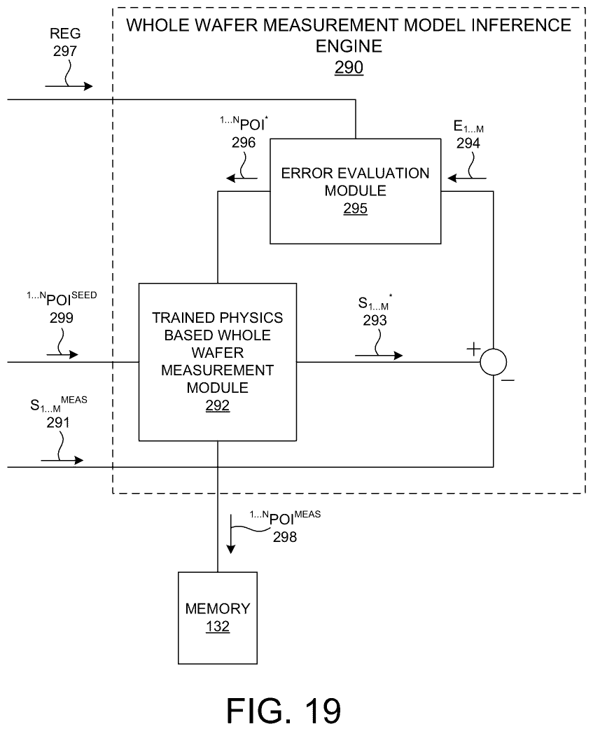

FIG. 19 is a diagram illustrative of a trained whole wafer measurement model inference engine 290 in another embodiment. The trained physics based whole wafer measurement module 291 employs a trained physics based whole wafer measurement model to determine values of N parameters of interest corresponding to M measurement sites measured across a wafer. In these embodiments, the measurement of the values of the parameters of interest is performed at all measurement sites across the wafer in parallel, i.e., all sites together.

As depicted in FIG. 19, whole wafer measurement model inference engine 290 includes a trained physics based whole wafer measurement module 292. In the embodiment depicted in FIG. 19, physics based whole wafer measurement module 292 estimates whole wafer measurement data, S_{1 . . . M}* 293, at the M measurement sites associated with seed values of the parameters of interest, ^{1 . . . N}POI_{1 . . . M}^{SEED} 299. The estimated whole wafer measurement data, S_{1 . . . M}* 293, is compared to actual whole wafer measurement data, S_{1 . . . M}^{MEAS} 291, collected by a metrology system or combination of metrology systems at M measurement sites. Error evaluation module 295 determines updated values of the parameters of interest, ^{1 . . . N}POI_{1 . . . M}* 296, that minimize a function characterizing a difference between the estimated whole wafer measurement data, S_{1 . . . M}* 293, and the actual whole wafer measurement data, S_{1 . . . M}^{MEAS} 291.

The updated values of the parameters of interest, ^{1 . . . N}POI_{1 . . . M}* 296, are communicated to the trained physics based whole wafer measurement module 292. Trained physics based whole wafer measurement module 292 updates the physics based whole wafer measurement model with the updated values of the parameters of interest for the next iteration of the inference process. The iteration continues until the objective function is minimized. The resulting estimated values of the parameters of interest are communicated to memory (e.g., memory 132).

Optionally, the optimization performed by error evaluation module 295 is regularized by one or more regularization terms, REG 297. In some embodiments, regularization terms 297 include expected wafer maps associated with each of the N parameters of interest. In these embodiments, the solution is driven toward a fit of the estimated whole wafer measurement data to the actual whole wafer measurement data at the M measurement sites and a fit of the values of the parameters of interest to the corresponding expected wafer maps employed as regularization terms.

In general, different forms of regularization are contemplated within the scope of this patent document, e.g., terms promoting smooth variations of values of parameters of interest across a wafer, terms penalizing discontinuities of values of parameters of interest across a wafer, etc.

In some embodiments, a physics based whole wafer model is trained and employed to infer values of a parameterized wafer map corresponding to each of the parameters of interest. The estimated values of the parameters of interest across a measured wafer are derived directly from the values of the parameterized wafer map based on the location of each measurement site as described hereinbefore.

In general, parameters of interest determined based on a trained whole wafer measurement model as described herein, include, but are not limited to: geometric parameters characterizing a measured structure, dispersion parameters characterizing a measured structure, process parameters characterizing a process employed to fabricate a measured structure, electrical properties of the measured structure, etc. Exemplary geometric parameters include critical dimensions (CD), overlay, etc. Exemplary process parameters include lithography focus, lithography dosage, etch time, etc.

In some examples, the DOE measurement data associated with measurements of instances of one or more DOE metrology targets at multiple sites across one or more wafers by a metrology system is simulated. The simulated data is generated from a parameterized model of the measurement of each of the one or more DOE metrology structures by the metrology system.

In some other examples, the DOE measurement data associated with measurements of instances of one or more DOE metrology targets at multiple sites across one or more wafers by a metrology system is actual measurement data collected by a metrology system or multiple instances of a metrology system. In some embodiments, the same metrology system or multiple instances of the metrology system is employed to collect the actual measurement data from instances of metrology targets having unknown values of one or more parameters of interest. In some embodiments, a different instance of the metrology system or multiple, different instances of the metrology system is employed to collect the actual measurement data from instances of metrology targets having unknown values of one or more parameters of interest.

In some embodiments, values of parameters of interest employed to train a whole wafer measurement model are derived from measurements of DOE wafers by a reference metrology system. The reference metrology system is a trusted measurement system that generates sufficiently accurate measurement results. In some examples, reference metrology systems are too slow to be used to measure wafers on-line as part of the wafer fabrication process flow, but are suitable for off-line use for purposes such as model training. By way of non-limiting example, a reference metrology system may include a stand-alone optical metrology system, such as a spectroscopic ellipsometer (SE), SE with multiple angles of illumination, SE measuring Mueller matrix elements, a single-wavelength ellipsometer, a beam profile ellipsometer, a beam profile reflectometer, a broadband reflective spectrometer, a single-wavelength reflectometer, an angle-resolved reflectometer, an imaging system, a scatterometer, such as a speckle analyzer, an X-ray based metrology system such as a small angle x-ray scatterometer (SAXS) operated in a transmission or grazing incidence mode, an x-ray diffraction (XRD) system, an x-ray fluorescence (XRF) system, an x-ray photoelectron spectroscopy (XPS) system, an x-ray reflectometer (XRR) system, a Raman spectroscopy system, an atomic force microscopy (AFM) system, a transmission electron microscopy system, a scanning electron microscopy system, a soft X-ray reflectometry system, an imaging based metrology system, a hyperspectral imaging based metrology system, a scatterometry overlay metrology system, or other technologies capable of determining device geometry.

In some embodiments, a measurement model trained as described herein is implemented as a neural network model. In other examples, a measurement model may be implemented as a linear model, a non-linear model, a polynomial model, a response surface model, a support vector machines model, a decision tree model, a random forest model, a kernel regression model, a deep network model, a convolutional network model, or other types of models.

In yet another further aspect, the measurement results described herein can be used to provide active feedback to a process tool (e.g., lithography tool, etch tool, deposition tool, etc.). For example, values of measured parameters determined based on measurement methods described herein can be communicated to an etch tool to adjust the etch time to achieve a desired etch depth. In a similar way etch parameters (e.g., etch time, diffusivity, etc.) or deposition parameters (e.g., time, concentration, etc.) may be included in a measurement model to provide active feedback to etch tools or deposition tools, respectively. In some example, corrections to process parameters determined based on measured device parameter values determined using a trained whole wafer measurement model may be communicated to the process tool. In one embodiment, computing system 130 determines values of one or more parameters of interest during process based on measured signals 111 received from a measurement system. In addition, computing system 130 communicates control commands to a process controller (not shown) based on the determined values of the one or more parameters of interest. The control commands cause the process controller to change the state of a process (e.g., stop the etch process, change the diffusivity, change lithography focus, change lithography dosage, etc.).

In some embodiments, the methods and systems for metrology of semiconductor devices as described herein are applied to the measurement of memory structures. These embodiments enable optical critical dimension (CD), film, and composition metrology for periodic and planar structures.

In some examples, the measurement models are implemented as an element of a SpectraShape® optical critical-dimension metrology system available from KLA-Tencor Corporation, Milpitas, California, USA. In this manner, the model is created and ready for use immediately after the spectra are collected by the system.

In some other examples, the measurement models are implemented off-line, for example, by a computing system implementing AcuShape® software available from KLA-Tencor Corporation, Milpitas, California, USA. The resulting, trained model may be incorporated as an element of an AcuShape® library that is accessible by a metrology system performing measurements.

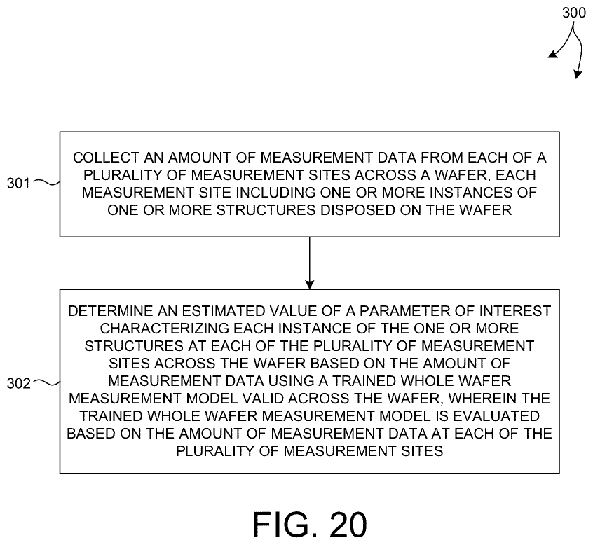

FIG. 20 illustrates a method 300 of training a whole wafer measurement model in at least one novel aspect. Method 300 is suitable for implementation by a metrology system such as metrology system 100 illustrated in FIG. 1 of the present invention. In one aspect, it is recognized that data processing blocks of method 300 may be carried out via a pre-programmed algorithm executed by one or more processors of computing system 130, or any other general purpose computing system. It is recognized herein that the particular structural aspects of metrology system 100 do not represent limitations and should be interpreted as illustrative only.

In block 301, an amount of measurement data is collected from each of a plurality of measurement sites across a wafer. Each measurement site includes one or more instances of one or more structures disposed on the wafer.

In block 302, an estimated value of a parameter of interest characterizing each instance of the one or more structures at each of the plurality of measurement sites across the wafer is determined based on the amount of measurement data using a trained whole wafer measurement model. The trained whole wafer measurement model is valid across the wafer, and is evaluated based on the amount of measurement data at each of the plurality of measurement sites.

In a further embodiment, system 100 includes one or more computing systems 130 employed to perform measurements of semiconductor structures based on a trained whole wafer measurement model in accordance with the methods described herein. The one or more computing systems 130 may be communicatively coupled to one or more spectrometers, active optical elements, process controllers, etc. In one aspect, the one or more computing systems 130 are configured to receive measurement data associated with spectral measurements of structures of wafer 101.

It should be recognized that one or more steps described throughout the present disclosure may be carried out by a single computer system 130 or, alternatively, a multiple computer system 130. Moreover, different subsystems of system 100 may include a computer system suitable for carrying out at least a portion of the steps described herein. Therefore, the aforementioned description should not be interpreted as a limitation on the present invention but merely an illustration.

In addition, the computer system 130 may be communicatively coupled to the spectrometers in any manner known in the art. For example, the one or more computing systems 130 may be coupled to computing systems associated with the spectrometers. In another example, the spectrometers may be controlled directly by a single computer system coupled to computer system 130.

The computer system 130 of system 100 may be configured to receive and/or acquire data or information from the subsystems of the system (e.g., spectrometers and the like) by a transmission medium that may include wireline and/or wireless portions. In this manner, the transmission medium may serve as a data link between the computer system 130 and other subsystems of system 100.

Computer system 130 of system 100 may be configured to receive and/or acquire data or information (e.g., measurement results, modeling inputs, modeling results, reference measurement results, etc.) from other systems by a transmission medium that may include wireline and/or wireless portions. In this manner, the transmission medium may serve as a data link between the computer system 130 and other systems (e.g., memory on-board system 100, external memory, or other external systems). For example, the computing system 130 may be configured to receive measurement data from a storage medium (i.e., memory 132 or an external memory) via a data link. For instance, spectral results obtained using the spectrometers described herein may be stored in a permanent or semi-permanent memory device (e.g., memory 132 or an external memory). In this regard, the spectral results may be imported from on-board memory or from an external memory system. Moreover, the computer system 130 may send data to other systems via a transmission medium. For instance, a measurement model or an estimated parameter value determined by computer system 130 may be communicated and stored in an external memory. In this regard, measurement results may be exported to another system.

Computing system 130 may include, but is not limited to, a personal computer system, mainframe computer system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the techniques described herein.

Various embodiments are described herein for a semiconductor measurement system that may be used for measuring a specimen within any semiconductor processing tool (e.g., an inspection system or a lithography system). The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A system comprising:
a metrology system including an illumination source and a detector configured to collect an amount of measurement data from each of a plurality of measurement sites across a wafer, each measurement site including one or more instances of one or more structures disposed on the wafer; and
a computing system configured to:
receive the amount of measurement data from each of the plurality of measurement sites on the wafer; and
determine an estimated value of a parameter of interest characterizing each instance of the one or more structures at each of the plurality of measurement sites across the wafer based on the amount of measurement data using a trained whole wafer measurement model valid across the wafer, wherein the trained whole wafer measurement model is evaluated based on the amount of measurement data at each of the plurality of measurement sites.

2. The system of claim 1, the computing system further configured to:
receive an amount of Design of Experiments (DOE) measurement data associated with measurements of one or more DOE instances of the one or more structures at each of a plurality of DOE measurement sites;
receive reference values of one or more parameters of interest characterizing the one or more DOE instances of the one or more structures at each of the plurality of DOE measurement sites; and
iteratively train the whole wafer measurement model based on the amount of DOE measurement data and the corresponding reference values at the plurality of DOE measurement sites in parallel.

3. The system of claim 2, the computing system further configured to:
receive an indication of a location of each of the plurality of DOE measurement sites, wherein the training of the whole wafer measurement model is also based on the location of each of the plurality of DOE measurement sites, and wherein the determining of the estimated value of the parameter of interest characterizing each instance of the one or more structures disposed on the wafer at each of the plurality of measurement sites is also based on a location of each of the plurality of measurement sites.

4. The system of claim 1, wherein the determining of the estimated value of the parameter of interest characterizing each instance of the one or more structures at each of the plurality of measurement sites across the wafer involves:
estimating values of coefficients of a function characterizing a parameterized wafer map of values of the parameters of interest at any location across the wafer; and
determining the value of the parameter of interest characterizing each instance of the one or more structures at each of the plurality of measurement sites across the wafer based on the estimated values of the coefficients values.

5. The system of claim 2, the computing system further configured to:
determine the reference values of the one or more parameters of interest characterizing the one or more DOE instances of the one or more structures at each of the plurality of DOE measurement sites based on a function characterizing a DOE parameterized wafer map of reference values of the parameters of interest at any location across the wafer; and
determine the amount of Design of Experiments (DOE) measurement data associated with measurements of the one or more DOE instances of the one or more structures at each of the plurality of DOE measurement sites based on a simulation of the metrology system including the reference values of the one or more parameters of interest.

6. The system of claim 5, the computing system further configured to:
estimate values of coefficients of a function characterizing the DOE parameterized wafer map of reference values of the parameters of interest at any location across the wafer based on measured or assumed values of the reference values of the parameters of interest.

7. The system of claim 6, the computing system further configured to:
estimate values of coefficients of a function characterizing a DOE parameterized wafer map of reference values of one or more ancillary parameters characterizing the one or more structures under measurement at any location across the wafer, wherein the simulation of the metrology system also includes the reference values of the one or more ancillary parameters.

8. The system of claim 2, wherein the reference values of one or more parameters of interest characterizing the one or more DOE instances of the one or more structures at each of the plurality of DOE measurement sites are generated by a process simulator.

9. The system of claim 2, wherein the reference values of one or more parameters of interest characterizing the one or more DOE instances of the one or more structures at each of the plurality of DOE measurement sites are measured by a trusted, reference metrology system.

10. The system of claim 1, wherein the trained whole wafer measurement model is machine learning based.

11. The system of claim 1, wherein the trained whole wafer measurement model is physics based.

12. The system of claim 1, wherein the amount of measurement data includes measurements of the one or more structures by at least one optical based metrology system, at least one x-ray based metrology system, or any combination thereof.

13. A method comprising:
collecting an amount of measurement data from each of a plurality of measurement sites across a wafer, each measurement site including one or more instances of one or more structures disposed on the wafer; and
determining an estimated value of a parameter of interest characterizing each instance of the one or more structures at each of the plurality of measurement sites across the wafer based on the amount of measurement data using a trained whole wafer measurement model valid across the wafer, wherein the trained whole wafer measurement model is evaluated based on the amount of measurement data at each of the plurality of measurement sites.

14. The method of claim 13, further comprising:
receiving an amount of Design of Experiments (DOE) measurement data associated with measurements of one or more DOE instances of the one or more structures at each of a plurality of DOE measurement sites;
receiving reference values of one or more parameters of interest characterizing the one or more DOE instances of the one or more structures at each of the plurality of DOE measurement sites; and
iteratively training the whole wafer measurement model based on the amount of DOE measurement data and the corresponding reference values at the plurality of DOE measurement sites in parallel.

15. The method of claim 14, further comprising:
receiving an indication of a location of each of the plurality of DOE measurement sites, wherein the training of the whole wafer measurement model is also based on the location of each of the plurality of DOE measurement sites, and wherein the determining of the estimated value of the parameter of interest characterizing each instance of the one or more structures disposed on the wafer at each of the plurality of measurement sites is also based on a location of each of the plurality of measurement sites.

16. The method of claim 13, wherein the determining of the estimated value of the parameter of interest characterizing each instance of the one or more structures at each of the plurality of measurement sites across the wafer involves:
estimating values of coefficients of a function characterizing a parameterized wafer map of values of the parameters of interest at any location across the wafer; and
determining the value of the parameter of interest characterizing each instance of the one or more structures at each of the plurality of measurement sites across the wafer based on the estimated values of the coefficients values.

17. The method of claim 14, further comprising:
determining the reference values of the one or more parameters of interest characterizing the one or more DOE instances of the one or more structures at each of the plurality of DOE measurement sites based on a function characterizing a DOE parameterized wafer map of reference values of the parameters of interest at any location across the wafer; and
determining the amount of Design of Experiments (DOE) measurement data associated with measurements of the one or more DOE instances of the one or more structures at each of the plurality of DOE measurement sites based on a simulation of the metrology system including the reference values of the one or more parameters of interest.

18. The method of claim 13, wherein the trained whole wafer measurement model is physics based or machine learning based.

19. A system comprising:
a metrology system including an illumination source and a detector configured to collect an amount of measurement data from each of a plurality of measurement sites across a wafer, each measurement site including one or more instances of one or more structures disposed on the wafer; and
a non-transitory, computer-readable medium including instructions that when executed by one or more processors of a computing system cause the computing system to:
receive the amount of measurement data from each of the plurality of measurement sites on the wafer; and
determine an estimated value of a parameter of interest characterizing each instance of the one or more structures at each of the plurality of measurement sites across the wafer based on the amount of measurement data using a trained whole wafer measurement model valid across the wafer, wherein the trained whole wafer measurement model is evaluated based on the amount of measurement data at each of the plurality of measurement sites.

20. The system of claim 19, the non-transitory, computer-readable medium further including instructions that when executed by one or more processors of the computing system cause the computing system to:
receive an amount of Design of Experiments (DOE) measurement data associated with measurements of one or more DOE instances of the one or more structures at each of a plurality of DOE measurement sites;
receive reference values of one or more parameters of interest characterizing the one or more DOE instances of the one or more structures at each of the plurality of DOE measurement sites; and
iteratively train the whole wafer measurement model based on the amount of DOE measurement data and the corresponding reference values at the plurality of DOE measurement sites in parallel.
